(19) United States
(12) Patent Application Publication
(10) Pub. No.: US 2002/0192854 A1
(43) Pub. Date: Dec. 19, 2002

(54) Method for packing semiconductor die

(76) Inventors: Johnson C. H. Tzu, Taipei (TW); Hsu Po Chih, Taoyuan (TW)

Correspondence Address: Chun M. Ng, BLAKELY, SOKOLOFF, TAYLOR & ZAFMAN LLP, Seventh Floor, 12400 Wilshire Boulevard, Los Angeles, CA, 90025-1026, US

(21) Appl. No.: 09/884,746

(22) Filed: Jun. 18, 2001

(51) Int. Cl. H01L 21/48; H01L 21/44

(52) U.S. Cl. 438/106; 438/111; 438/118; 438/123

(57) ABSTRACT

A method is provided for packing semiconductor die. The method includes the following steps: Firstly, a metal frame having a specific pattern is provided. Then, a material on the backside surface of a plurality of dice is laminated. The plurality of dice is located upon the metal frame. A metal wire is bonded to connect the plurality of dice below. Next, first molding the plurality of dice and parts of the metal frame to expose parts of the metal frame is achieved by a chemical compound to seal the plurality of dice. Then, the second individual/conformal molding the plurality of dice is carried out by the chemical compound. Next, a plurality of metal balls is placed to connect under other parts of the metal frame as an individual/conformal die package. Finally, the individual die package is punched to pack the semiconductor die.

### BACKGROUND OF THE INVENTION

1. Field of the Invention

The present invention relates to a semiconductor die package, and more specifically, by using lead frame and BGA method.

2. Description of the Prior Art

Developments in interconnect and packing is quite modest in comparison. The renewed interest in the high-density hybrid is driven by the requirement to handle large numbers of IC interconnections, the increasing clock rate of digital systems and the desire to pack greater functionality into smaller spaces. Therefore, the number of a package's leads becomes more and more. For example, a package known as Pin Grid Array (PGA) can accommodate over 200 leads. An important consideration in making small, high speed and high-density devices is providing packages capable of the spreading heat generated by the devices.

A further problem confronting the technology is the relentless need for more I/O per chip. A conventional lead frame package, such as SOP, PQFP, has a limitation to increase the number of the package's lead. In addition, the maximum speed of the lead frame package is less than 100 MHz, so that cannot meet the manufacturers' desire. One response to the requirement of providing packages for high speed and density devices has been developed. One such package type is plastic ball grid array (PBGA) that uses a bismaleimidetraizine (BT) as a substrate. The PBGA offers many advantages over conventional packages such as solder ball I/O and high speed. The PBGA package has high speed due to a short path for signal transformation. The solder balls are set on a package surface in a matrix array, which can provide more signal contacts. Although the PBGA has a shorter path for spreading heat than a conventional package, but a heater spreader or a heat slug can not be set on the backside of a die paddle due to the structure of the PBGA. Further, the substrate of the PBGA is made of BT so that the efficiency of spreading heat is poorer than the lead frame package.

As the mentioned above, the increasing clock rate of digital systems and the desire will pack greater functionality into smaller spaces. Therefore, the number of a package's leads becomes more and more. An important consideration in making small, high speed and high-density devices is providing packages capable of the spreading heat generated by the devices. A further problem confronting the technology is the relentless need for more I/O per chip. A conventional lead frame package, such as SOP, PQFP, has a limitation to increase the number of the package's lead. In addition, the maximum speed of the lead frame package cannot meet the manufacturers' desire.

One response to the requirement of providing packages for high speed and density devices has been developed. One such package type is ball grid array (BGA) that uses a bismaleimidetraizine (BT) as a substrate. For high I/O count IC chips, Ball grid array (BGA) packages have been used that can have more I/Os than QFPs. BGAs connect to PCBs using balls instead of pins or leads. Solder bumps or balls are attached to the lower surface of a substrate. These solder bumps or balls, in turn, provide the I/O connections of the BGA package. Such a configuration allows an increase in the number of I/O interconnects over conventional packages.

The BGA offers many advantages over conventional packages such as solder ball I/O and high speed. The BGA package has high speed due to a short path for signal transformation. The solder balls are set on a package surface in a matrix array that can provide more signal contacts. One type of the BGA package is called chip scale packages (CSP) that has a scale slightly larger than a chip. At present, several difficulties still limit the broad applications of a chip scale packaging technology in the field of package industry. One of the major difficulties is related to the issue of CSP production cost such as the manufacture equipment, the materials, the yields of each process. A low cost CSP package manufactured to produce highly reliable IC packages cannot be easily achieved.

As the mentioned above, with the rapid advances in wafer fabrication process technology, IC designers are always tempted to increase the chip level integration at an ever-faster pace. It has been the trend in integrated circuit (IC) technology to increase the density of semiconductor devices per unit area of silicon wafer. It follows then that the semiconductor devices, such as transistors and capacitors, must be made smaller and smaller. Further, the manufacturers of the devices are striving to reduce the size while simultaneously increasing their speed.

### SUMMARY OF THE INVENTION

In accordance with the present invention, a method is provided for packing semiconductor die that substantially increases the semiconductor speed and reduces the package size.

It is object for the present invention that the high frequency requirement is easily achieved.

It is another object for the present invention that the package cost can be exactly decreased.

It is other object for the present invention that the cycle time is shorter than before.

In the first feature of the embodiment, the method for packing a semiconductor die is described as the followings:

Firstly, a metal frame having a specific pattern is provided. Then, a material on the backside surface of a plurality of dice is laminated by using a adhesive material as a tape. The plurality of dice is located upon the metal frame. A metal wire is bonded to connect the plurality of dies below. Next, first molding the plurality of dice and parts of the metal frame to expose parts of the metal frame is achieved by a chemical compound. Then, the second individual molding the plurality of dice is carried out by the chemical compound. Next, a plurality of metal balls is placed to connect under other parts of the metal frame as an individual die package. Finally, the individual die package is punched to pack the semiconductor die.

In the second feature of the embodiment, the method for packing a semiconductor die is described as the followings:

Firstly, a metal frame having a specific pattern is provided. Then, a material on the backside surface of a plurality of dice is laminated by using an adhesive material as a tape. The plurality of dice is located upon the metal frame. A metal wire is bonded to connect the plurality of dice below. Next, first molding the plurality of dice and parts of the metal frame to expose parts of the metal frame is achieved by a chemical compound. Then, the second conformal molding the plurality of dice is carried out by the chemical compound. Next, a plurality of metal balls is placed to connect under other parts of the metal frame as an conformal die package. Finally, the conformal die package is singulated to pack the semiconductor die.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIGS. 1A to 1G are illustrative of various components in the cross-section with first embodiment of the present invention;

FIGS. 2A to 2G are illustrative of various components in the cross-section with second embodiment of the present invention;

FIGS. 3A to 3F are illustrative of various components in the cross-section with third embodiment of the present invention;

FIGS. 4A to 4F are illustrative of various components in the cross-section with fourth embodiment of the present invention;

FIGS. 5A to 5G are illustrative of various components in the cross-section with fifth embodiment of the present invention;

FIGS. 6A to 6G are illustrative of various components in the cross-section with sixth embodiment of the present invention;

FIGS. 7A to 7F are illustrative of various components in the cross-section with seventh embodiment of the present invention;

FIGS. 8A to 8F are schematic diagrams showing the cross-section of eighth embodiment of present invention;

FIGS. 9A to 9F are schematic diagrams showing the cross-section of ninth embodiment of present invention; and

FIGS. 10A to 10E are schematic diagrams showing the cross-section of tenth embodiment of present invention.

### DESCRIPTION OF THE PREFERRED EMBODIMENT

The following is a description of the present invention. The invention will firstly be described with reference to one exemplary structure. Some variations will then be described as well as advantages of the present invention. A preferred method of fabrication will then be discussed. An alternate, asymmetric embodiment will then be described along with the variations in the process flow to fabricate this embodiment.

Moreover, while the present invention is illustrated by a number of preferred embodiments directed to semiconductor package, it is not intended that these illustrations be a limitation on the scope or applicability of the present invention. Further, while the illustrative examples use lead frame, it should be recognized that the ceramic portions might be replaced with plastic portions. Thus, it is not intended that the semiconductor devices of the present invention be limited to the structures illustrated. These devices are included to demonstrate the utility and application of the present invention to presently preferred embodiments.

Therefore, the spirit of the proposed invention can be explained and understood by the following embodiments with corresponding figures. Especially, there is a method for packing a semiconductor wafer according to preferred embodiment of the present invention can be described the followings:

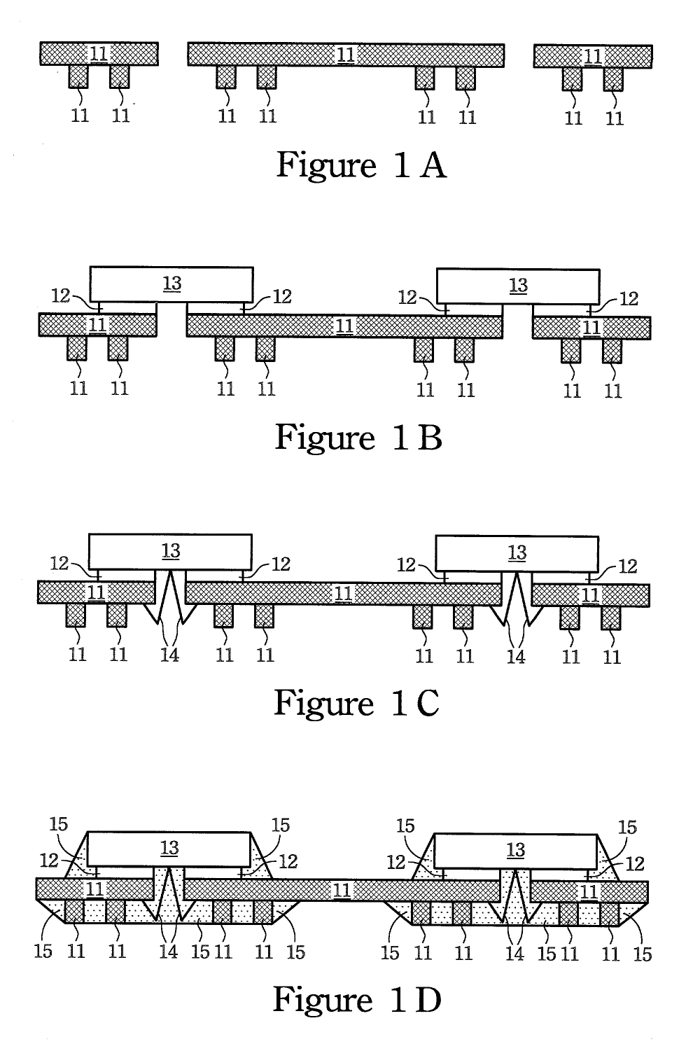

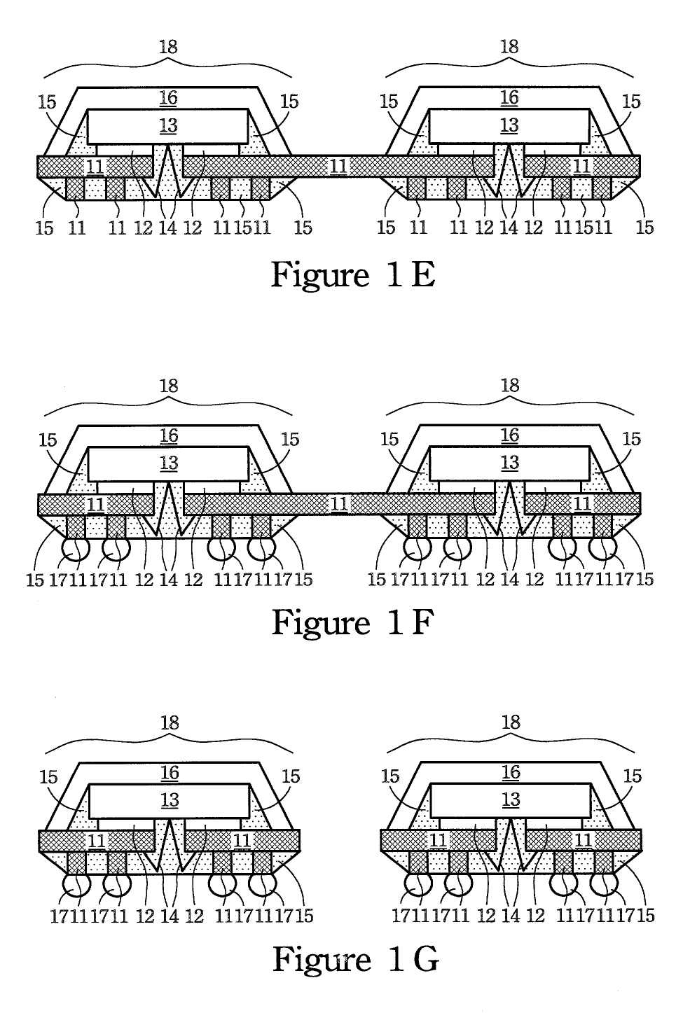

Firstly, the first embodiment of the present invention is showed as FIG. 1A. A metal frame 11, such as lead frame 11 is provided and the metal frame 11 is formed as a specific pattern. Especially the specific pattern is defined by the lithography including stamping process etc.

With reference to FIG. 1B, a material 12 is laminated on the backside surface of a plurality of dice 13. The material 12 is used by adhesive material as a tape. Still referring to FIG. 1B, the plurality of dice 13 is located upon the metal frame 11. Here, the plurality of dice 13 are formed from the semiconductor wafer or semiconductor chip.

Referring FIG. 1C, a metal wire 14 is bonded to connect the plurality of dice 13 below. Normally the metal wire 14 is formed by the gold wire.

Next, as FIG. 1D, first molding the plurality of dice 13 and parts of the metal frame 11 are achieved to expose parts of the metal frame 11 by a chemical compound such as plastic. Therefore, the first chemical compound housing 15 is formed around the plurality of dice 13. External pressure is introduced in the step to prevent the chemical compound from coating on the lower surface of the metal frame 11 portions.

Then, it is illustrated as FIG. 1E, second individual molding the plurality of dice 13 can be accomplished by the chemical compound, such as plastic or ceramic. The second chemical compound housing 16 is formed and covered on the above first chemical compound housing 16 and parts of the top surface of the metal frame 11.

As FIG. 1F shows, a plurality of metal balls 17 is placed to connect under other parts of the metal frame 11, which is the bottom portion of the metal frame 11, so that the individual die package 18 is obtained.

Finally, it is shown as FIG. 1G, the individual die package 18 is punched to become as a finished die package 19 in order to pack the semiconductor die. Especially, the punching line is set therebetween any two of the individual die package 18.

In the practical, the first embodiment of the invention is provided for the 64M SDRAM fabrication. In addition, the die specification is designed for the 0.18 um wire width and the package size is about 9×12 mm.

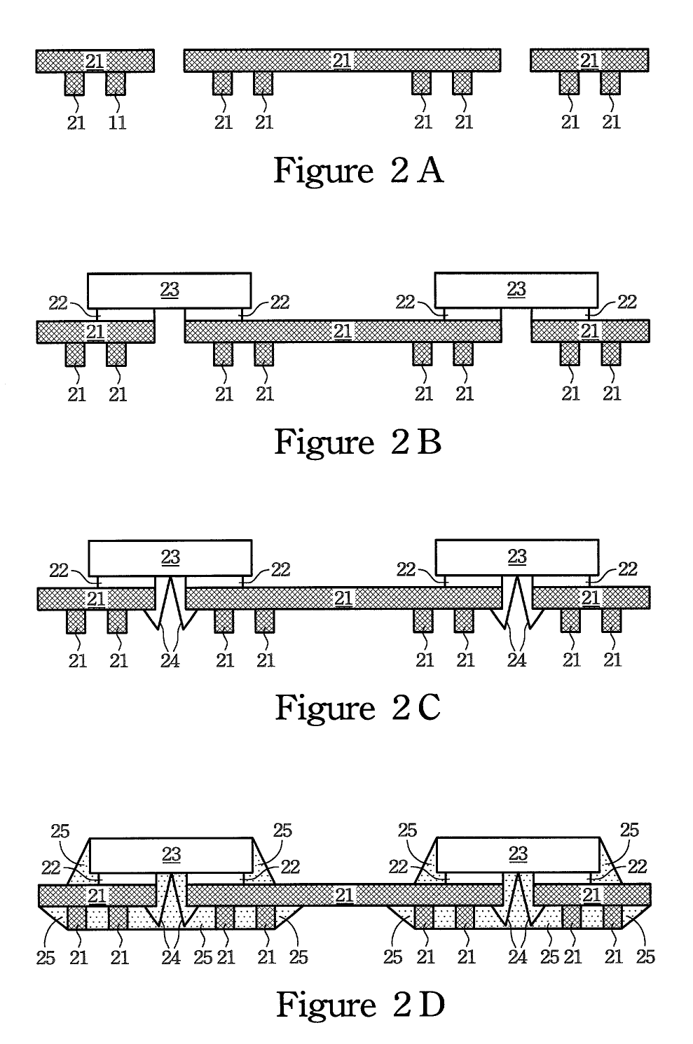

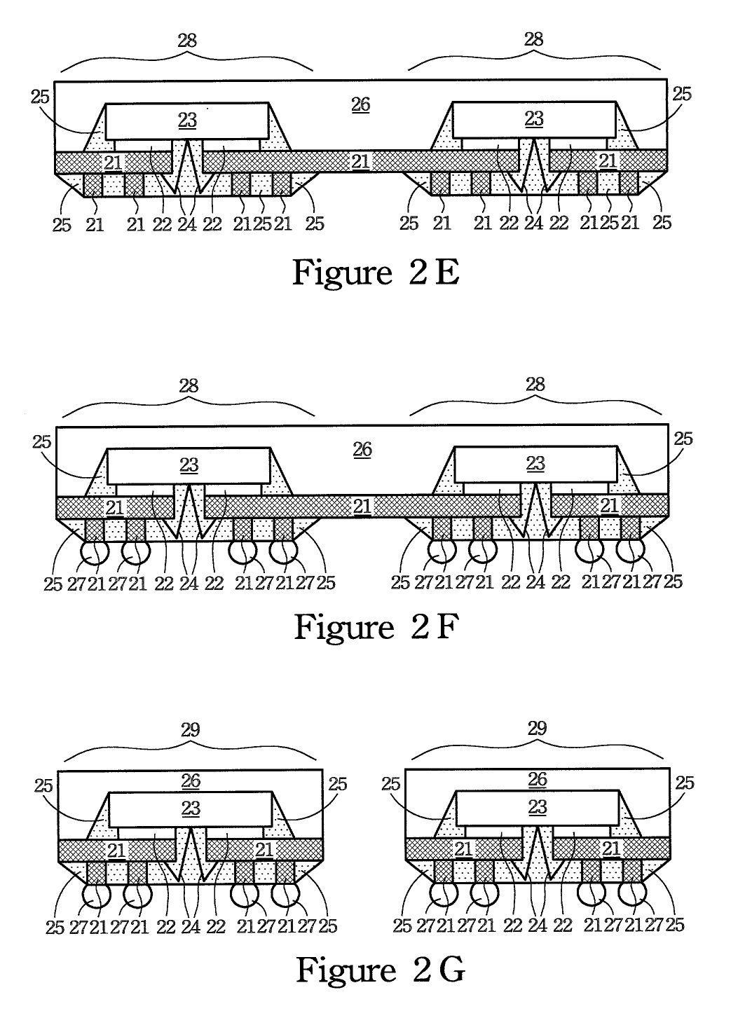

The second embodiment of the present invention is showed as FIG. 2A. Firstly, a metal frame 21, such as lead frame 21 is provided and the metal frame 21 is formed as a specific pattern. Especially the specific pattern is defined by the lithography including stamping process etc.

With reference to FIG. 2B, a material 22 is laminated on the backside surface of a plurality of dice 23. The material 22 is used by adhesive material as a tape. Still referring to FIG. 1B, the plurality of dice 23 is located upon the metal frame 21. Here, the plurality of dice 23 is formed from the semiconductor wafer or semiconductor chip.

Referring FIG. 2C, a metal wire 24 is bonded to connect the plurality of dice 23 below. Normally the metal wire 24 is formed by the gold wire.

Next, as FIG. 2D, first molding the plurality of dies 23 and parts of the metal frame 21 are achieved to expose parts of the metal frame 21 by a chemical compound such as plastic. Therefore, the first chemical compound housing 25 is formed around the plurality of dice 23. External pressure is introduced in the step to prevent the chemical compound from coating on the lower surface of the metal frame 21 portions.

Then, it is illustrated as FIG. 2E, second conformal molding the plurality of dice 23 can be accomplished by the chemical compound, such as plastic, ceramic or glass. The second chemical compound housing 25 is formed and covered on the above first chemical compound housing 25 and parts of the top surface of the metal frame 21.

As FIG. 2F shows, a plurality of metal balls 27 is placed to connect under other parts of the metal frame 11, which is the bottom portion of the metal frame 11, so that the conformal die package 28 is obtained.

Finally, it is shown as FIG. 2G, the conformal die package 28 is singulated to become as a finished die package 29 in order to pack the semiconductor die. Especially, the punching line is set therebetween any two of the conformal die package 28.

In the practical, using the lead frame and BGA, the second embodiment of the invention is provided for the 64M SDRAM fabrication. Especially the die specification is designed for the 0.18 um wire width and the package size is about 9×12 mm.

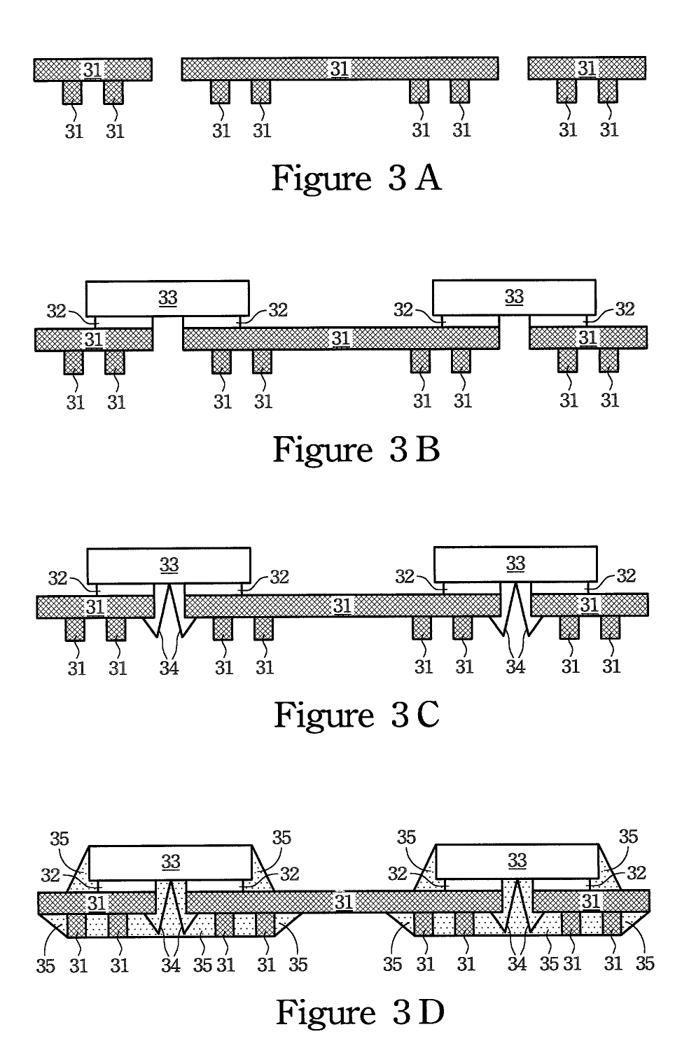

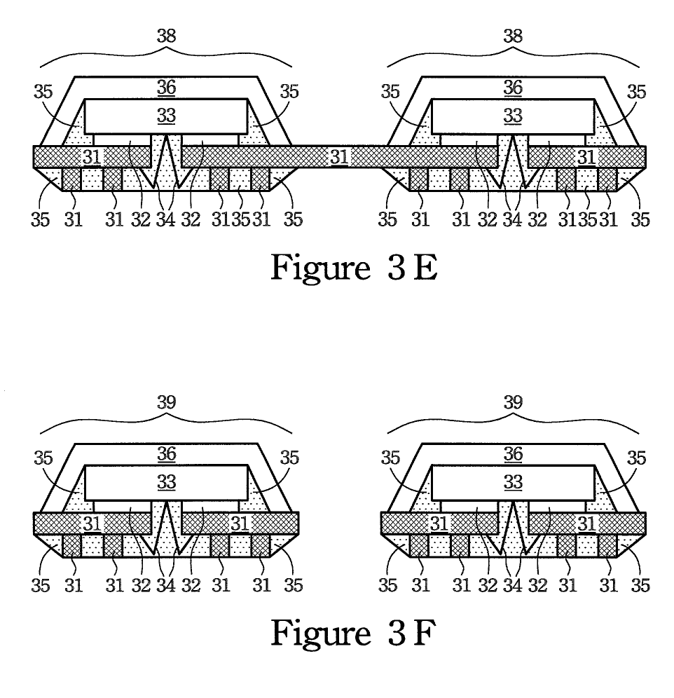

Firstly, the third embodiment of the present invention is showed as FIG. 3A. A metal frame 31, such as lead frame 31 is provided and the metal frame 31 is formed as a specific pattern. Especially the specific pattern is defined by the lithography including stamping process etc.

With reference to FIG. 3B, a material 32 is laminated on the backside surface of a plurality of dice 33. The material 32 is used by adhesive material as a tape. Still referring to FIG. 3B, the plurality of dice 33 is located upon the metal frame 31. Here, the plurality of dice 13 are formed from the semiconductor wafer or semiconductor chip.

Referring FIG. 3C, a metal wire 34 is bonded to connect the plurality of dice 33 below. Normally the metal wire 34 is formed by the gold wire.

Next, as FIG. 3D, first molding the plurality of dice 33 and parts of the metal frame 31 are achieved to expose parts of the metal frame 31 by a chemical compound such as plastic. Therefore, the first chemical compound housing 35 is formed around the plurality of dice 33. External pressure is introduced in the step to prevent the chemical compound from coating on the lower surface of the metal frame 31 portions.

Then, it is illustrated as FIG. 3E, second individual molding the plurality of dice 33 can be accomplished by the chemical compound, such as plastic or ceramic. The second chemical compound housing 36 is formed and covered on the above first chemical compound housing 35 and parts of the top surface of the metal frame 31, so that the individual die package 38 is obtained.

Finally, it is shown as FIG. 3F, the individual die package 38 is punched to become as a finished die package 39 in order to pack the semiconductor die.

In the practical, the third embodiment of the invention is provided for the 64M SDRAM fabrication. In addition, the die specification is designed for the 0.18 um wire width and the package size is about 9×12 mm.

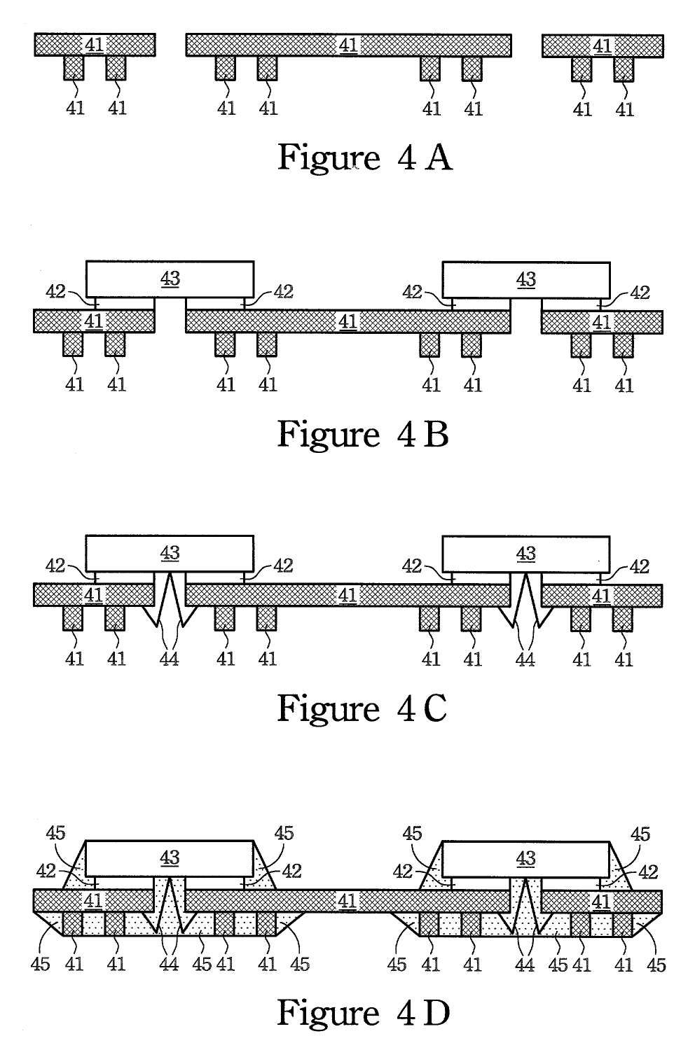

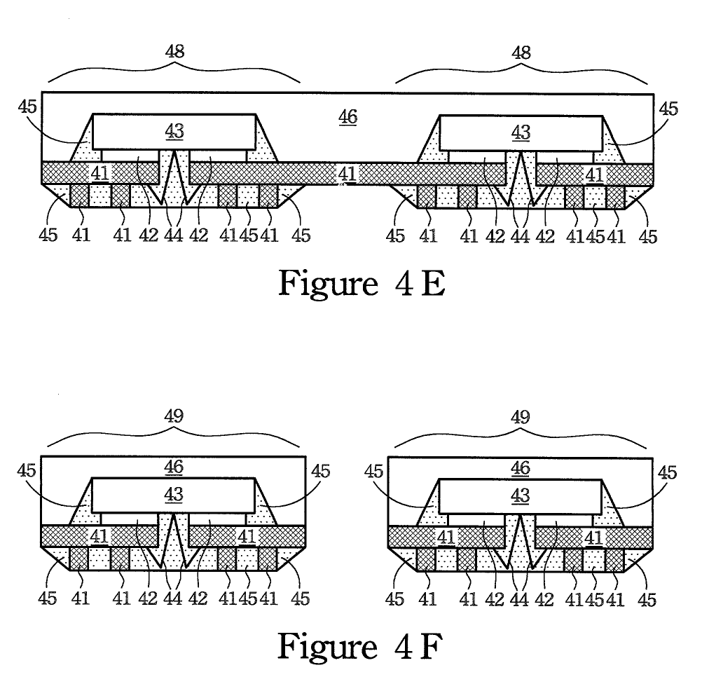

The fourth embodiment of the present invention is showed as FIG. 4A. Firstly, a metal frame 41, such as lead frame 41 is provided and the metal frame 41 is formed as a specific pattern. Especially the specific pattern is defined by the lithography including stamping process etc.

With reference to FIG. 4B, a material 42 is laminated on the backside surface of a plurality of dice 43. The material 42 is used by adhesive material as a tape. Still referring to FIG. 4B, the plurality of dice 43 is located upon the metal frame 41. Here, the plurality of dice 43 is formed from the semiconductor wafer or semiconductor chip.

Referring FIG. 4C, a metal wire 44 is bonded to connect the plurality of dice 43 below. Normally the metal wire 44 is formed by the gold wire.

Next, as FIG. 4D, first molding the plurality of dice 43 and parts of the metal frame 41 are achieved to expose parts of the metal frame 41 by a chemical compound such as plastic. Therefore, the first chemical compound housing 45 is formed around the plurality of dice 43. External pressure is introduced in the step to prevent the chemical compound from coating on the lower surface of the metal frame 41 portions.

Then, it is illustrated as FIG. 4E, second conformal molding the plurality of dice 43 can be accomplished by the chemical compound, such as plastic or ceramic. The second chemical compound housing 46 is formed and covered on the above first chemical compound housing 45 and parts of the top surface of the metal frame 41 so that the conformal die package 48 is obtained.

Finally, it is shown as FIG. 4F, the conformal die package 48 is singulated to become as a finished die package 49 in order to pack the semiconductor die.

In the practical, using the lead frame and BGA, the fourth embodiment of the invention is provided for the 64MSDRAM fabrication. Especially the die specification is designed for the 0.18 um wire width and the package size is about 9×12 mm.

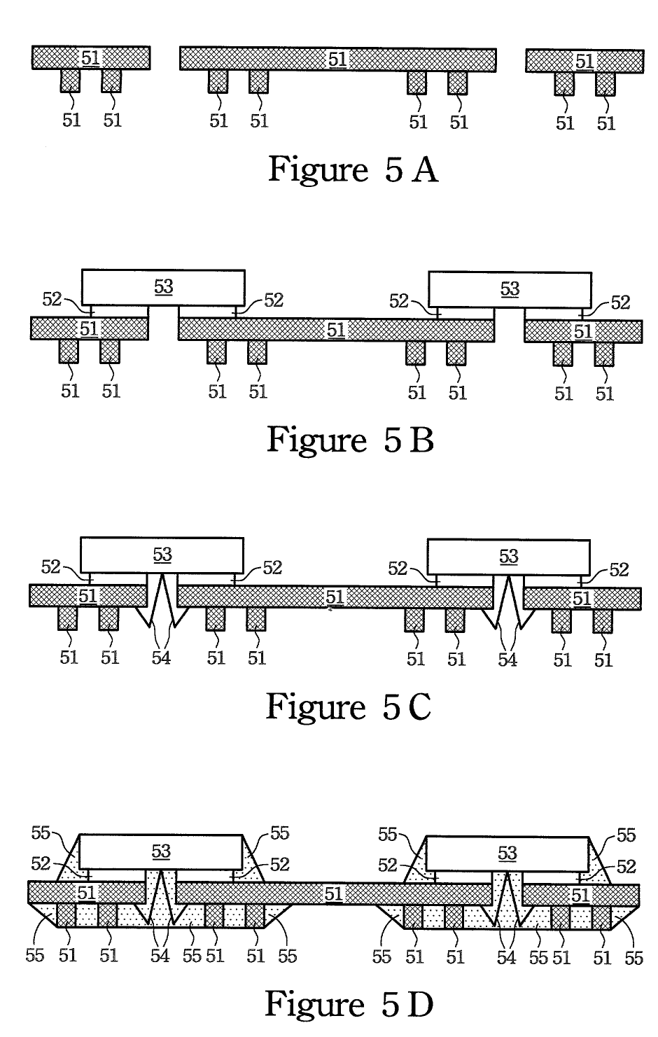

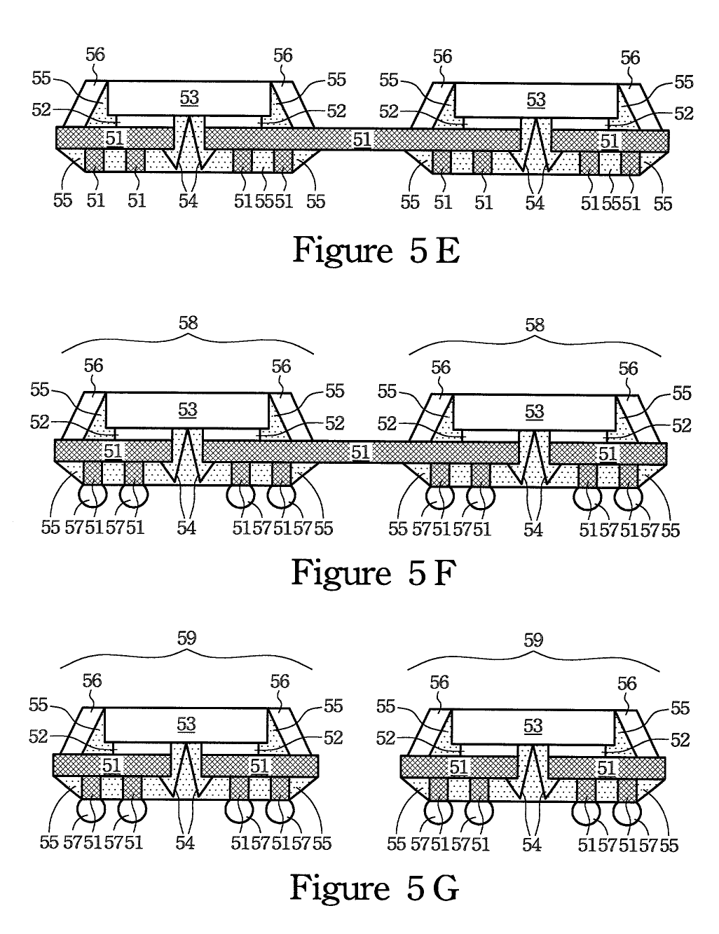

Firstly, the fifth embodiment of the present invention is showed as FIG. 5A. A metal frame 51, such as lead frame 51 is provided and the metal frame 51 is formed as a specific pattern. Especially the specific pattern is defined by the lithography including stamping process etc.

With reference to FIG. 5B, a material 52 is laminated on the backside surface of a plurality of dice 53. The material 52 is used by adhesive material as a tape. Still referring to FIG. 5B, the plurality of dice 53 is located upon the metal frame 51. Here, the plurality of dice 53 are formed from the semiconductor wafer or semiconductor chip.

Referring FIG. 5C, a metal wire 54 is bonded to connect the plurality of dice 53 below. Normally the metal wire 54 is formed by the gold wire.

Next, as FIG. 5D, first molding around a first side of the plurality of dice 53 as a first housing 55 and parts of the metal frame is achieved to expose another parts of the metal frame 51 by a chemical compound such as plastic. Especially a top surface of the plurality of dice 53 is exposed. External pressure is introduced in the step to prevent the chemical compound from coating on the lower surface of the metal frame 51 portions.

Then, as FIG. 5E, second individual molding around a second side of the first housing 55 is carried out as a second housing 56 by the chemical compound. Especially the top surface of the plurality of dice 53 is exposed, so that the cooling effect is better than before.

As FIG. 5F shows, a plurality of metal balls 57 is placed to connect under other parts of the metal frame 51, which is the bottom portion of the metal frame 51 so that the individual die package 58 is obtained.

Finally, it is shown as FIG. 5G, the individual die package is punched to become as a finished die package 59 in order to pack the semiconductor die. Especially, the punching line is set therebetween any two of the individual die package 58.

In the practical, the fifth embodiment of the invention is provided for the 64M SDRAM fabrication. In addition, the die specification is designed for the 0.18 um wire width and the package size is about 9×12 mm.

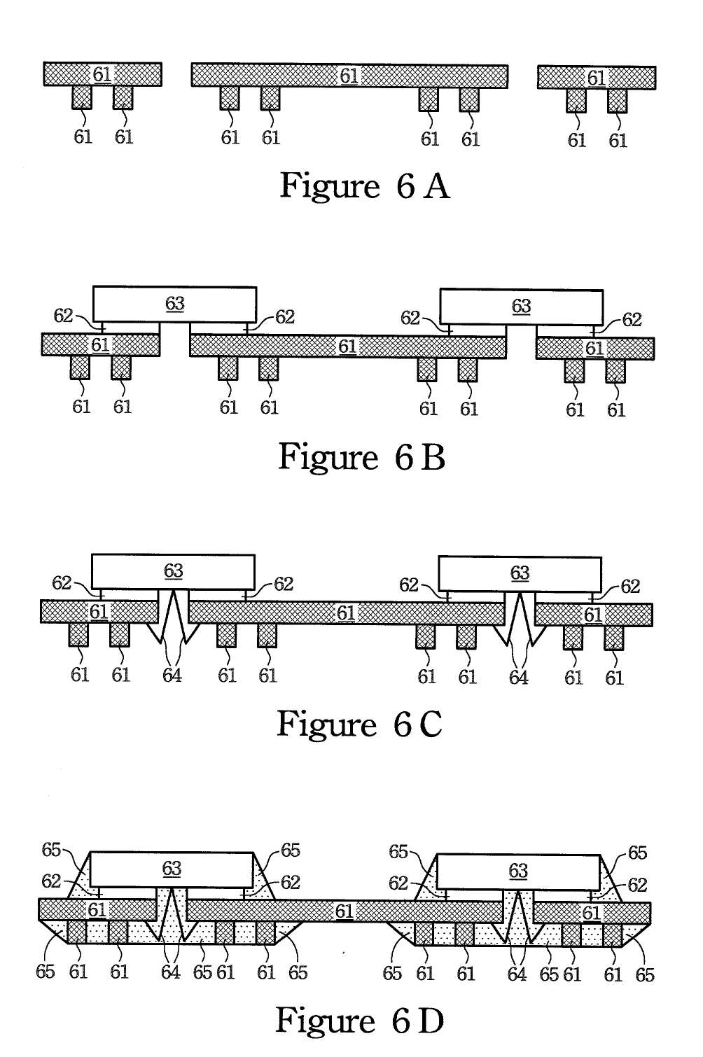

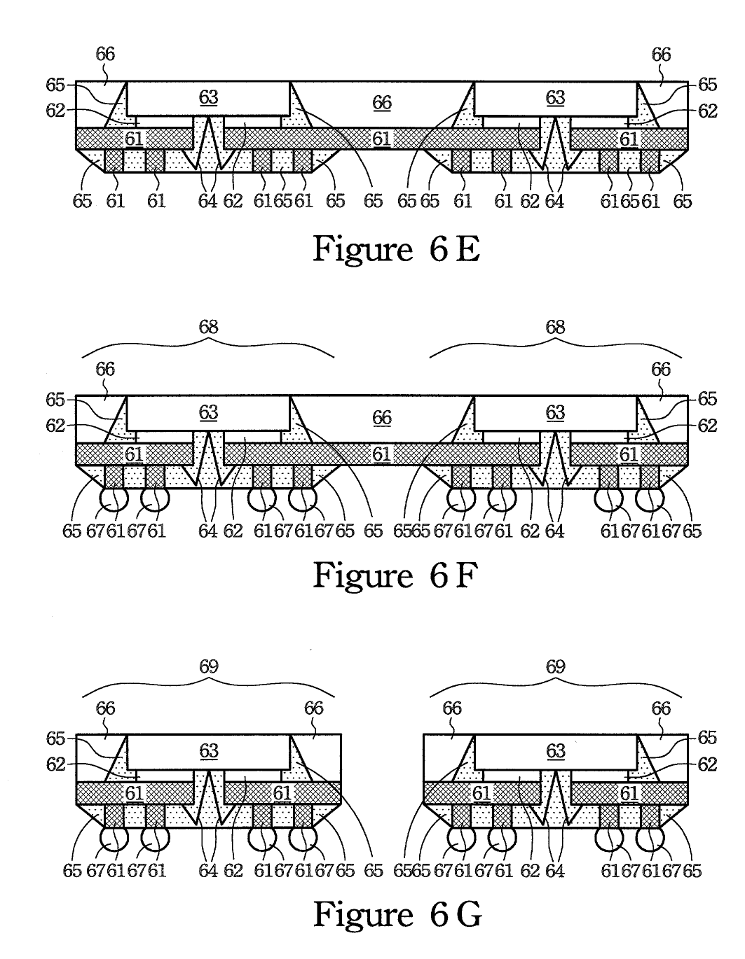

The sixth embodiment of the present invention is showed as FIG. 6A. Firstly, a metal frame 61, such as lead frame 61 is provided and the metal frame 61 is formed as a specific pattern. Especially the specific pattern is defined by the lithography including stamping process etc.

With reference to FIG. 6B, a material 62 is laminated on the backside surface of a plurality of dice 63. The material 62 is used by adhesive material as a tape. Still referring to FIG. 6B, the plurality of dies 63 is located upon the metal frame 61. Here, the plurality of dice 63 is formed from the semiconductor wafer or semiconductor chip.

Referring FIG. 6C, a metal wire 64 is bonded to connect the plurality of dice 63 below. Normally the metal wire 64 is formed by the gold wire.

Next, as FIG. 6D, first molding around a first side of the plurality of dice 63 as a first housing 65 and parts of the metal frame is achieved to expose another parts of the metal frame 61 by a chemical compound such as plastic. Especially a top surface of the plurality of dice 63 is exposed. External pressure is introduced in the step to prevent the chemical compound from coating on the lower surface of the metal frame 61 portions.

Then, as FIG. 6E, second conformable molding around a second side of the first housing 65 is carried out as a second housing 66 by the chemical compound. Especially the top surface of the plurality of dice 63 is exposed, so that the cooling effect is better than before.

As FIG. 6F shows, a plurality of metal balls 67 is placed to connect under other parts of the metal frame 61, which is the bottom portion of the metal frame 61 so that the conformal die package 68 is obtained.

Finally, it is shown as FIG. 6G, the conformal die package 68 is singulated to become as a finished die package 69 in order to pack the semiconductor die.

In the practical, using the lead frame and BGA, the sixth embodiment of the invention is provided for the 64M SDRAM fabrication. Especially the die specification is designed for the 0.18 um wire width and the package size is about 9×12 mm.

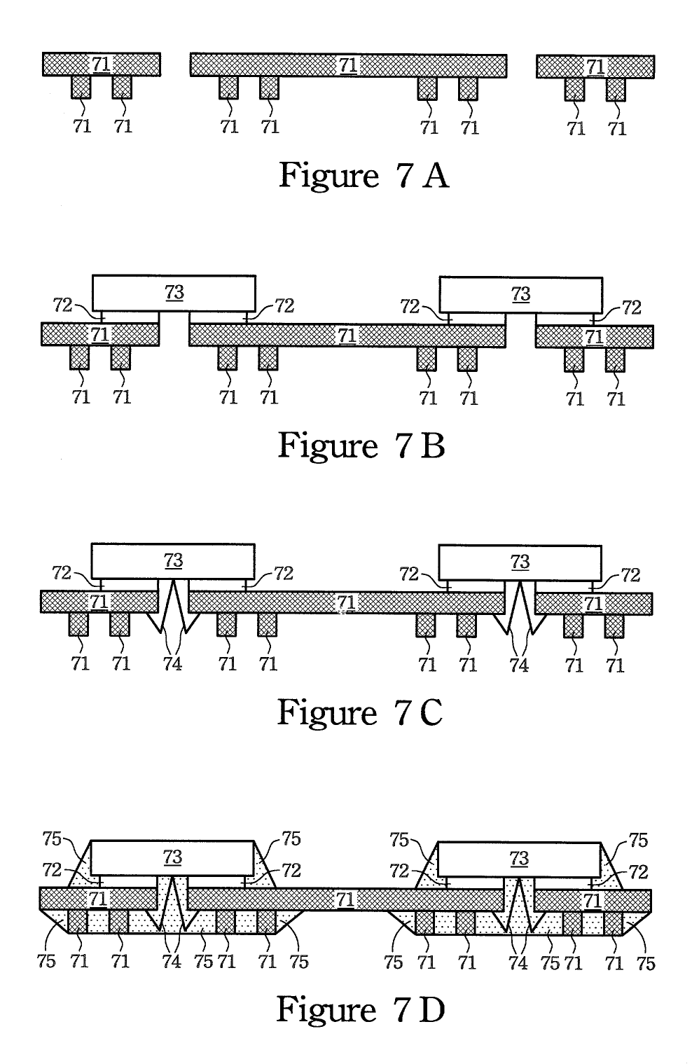

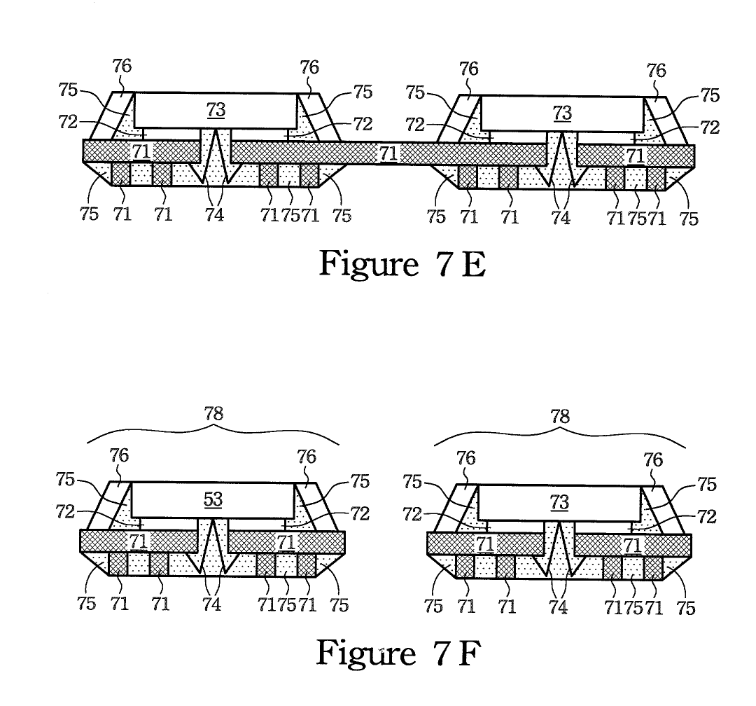

Firstly, the seventh embodiment of the present invention is showed as FIG. 7A. A metal frame 71, such as lead frame 71 is provided and the metal frame 71 is formed as a specific pattern. Especially the specific pattern is defined by the lithography including stamping process etc.

With reference to FIG. 7B, a material 72 is laminated on the backside surface of a plurality of dice 73. The material 72 is used by adhesive material as a tape. Still referring to FIG. 7B, the plurality of dice 73 is located upon the metal frame 71. Here, the plurality of dice 73 are formed from the semiconductor wafer or semiconductor chip.

Referring FIG. 7C, a metal wire 74 is bonded to connect the plurality of dice 73 below. Normally the metal wire 74 is formed by the gold wire.

Next, as FIG. 7D, first molding around a first side of the plurality of dice 73 as a first housing 75 and parts of the metal frame is achieved to expose another parts of the metal frame 71 by a chemical compound such as plastic. Especially a top surface of the plurality of dice 73 is exposed. External pressure is introduced in the step to prevent the chemical compound from coating on the lower surface of the metal frame 71 portions.

Then, as FIG. 7E, second individual molding around a second side of the first housing 75 is carried out as a second housing 76 by the chemical compound. Especially the top surface of the plurality of dice 73 is exposed as the individual die package 77, so that the cooling effect is better than before.

Finally, it is shown as FIG. 7F, the individual die package 77 is punched to become as a finished die package 78 in order to pack the semiconductor die.

In the practical, the seveth embodiment of the invention is provided for the 64M SDRAM fabrication. In addition, the die specification is designed for the 0.18 um wire width and the package size is about 9×12 mm.

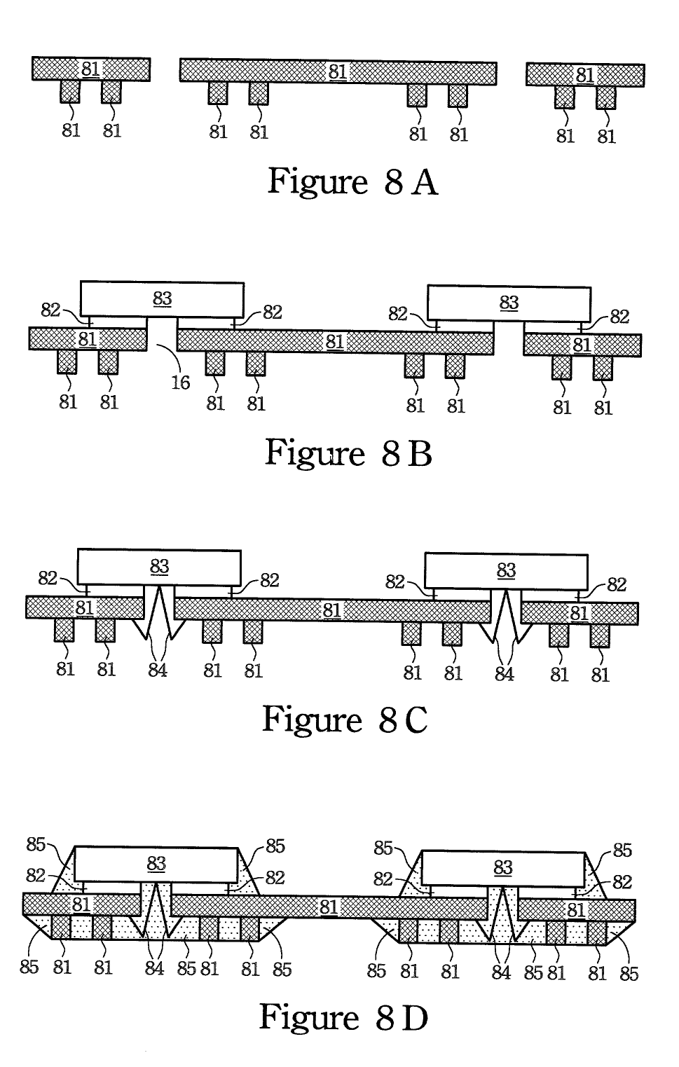

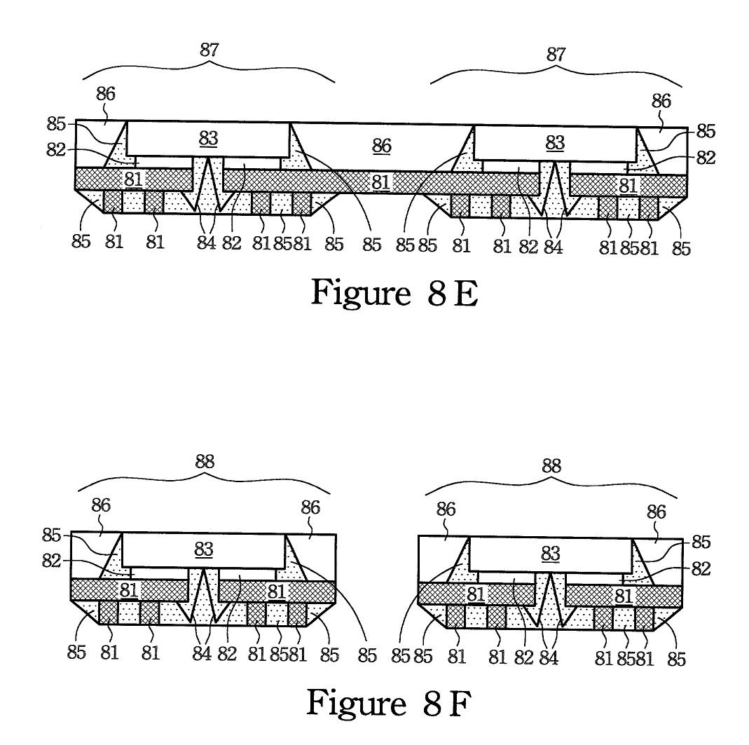

The eighth embodiment of the present invention is showed as FIG. 8A. Firstly, a metal frame 81, such as lead frame 81 is provided and the metal frame 81 is formed as a specific pattern. Especially the specific pattern is defined by the lithography including stamping process etc.

IV With reference to FIG. 8B, a material 82 is laminated on the backside surface of a plurality of dice 83. The material 82 is used by adhesive material as a tape. Still referring to FIG. 8B, the plurality of dice 83 is located upon the metal frame 81. Here, the plurality of dies 83 is formed from the semiconductor wafer or semiconductor chip.

Referring FIG. 8C, a metal wire 84 is bonded to connect the plurality of dice 83 below. Normally the metal wire 84 is formed by the gold wire.

Next, as FIG. 8D, first molding around a first side of the plurality of dice 83 as a first housing 85 and parts of the metal frame is achieved to expose another parts of the metal frame 81 by a chemical compound such as plastic. Especially a top surface of the plurality of dice 83 is exposed. External pressure is introduced in the step to prevent the chemical compound from coating on the lower surface of the metal frame 81 portions.

Then, as FIG. 8E, second conformal molding around a second side of the first housing 85 is carried out as a second housing 86 by the chemical compound. Especially the top surface of the plurality of dice 83 is exposed as the conformal die package 87, so that the cooling effect is better than before.

Finally, it is shown as FIG. 8F, the conformal die package 87 is singulated to become as a finished die package 88 in order to pack the semiconductor die.

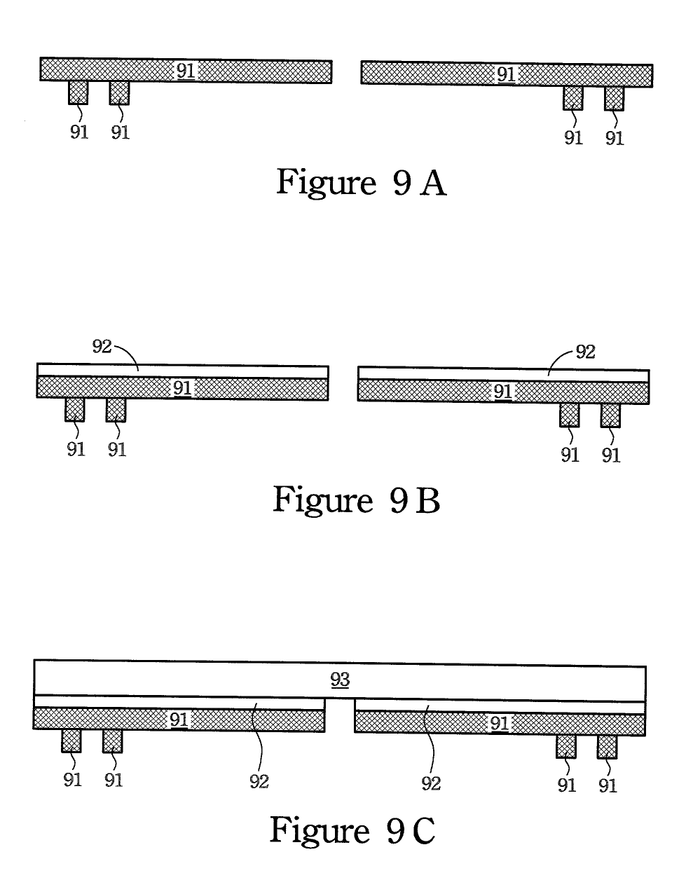

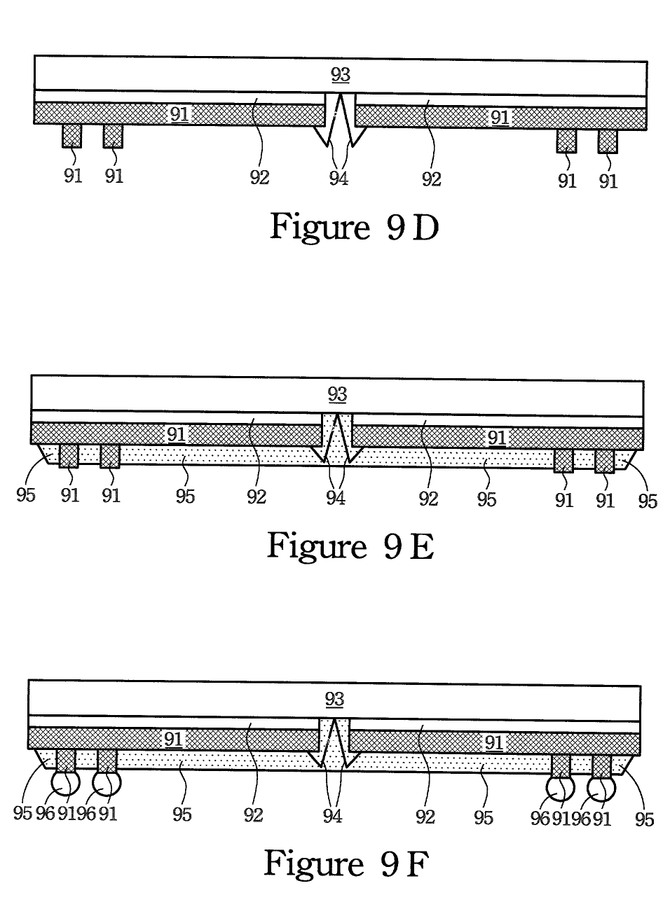

Next, the ninth embodiment of the present invention is showed as FIG. 9A. A metal frame 91, such as lead frame 91 is provided and the metal frame 91 is formed as a specific pattern. Especially the specific pattern is defined by the lithography including stamping process etc.

With reference to FIG. 9B, a material 92 is laminated on the backside surface of a die 93. The material 92 is used by adhesive material as a tape.

Referring to FIG. 9C, the die 93 is located upon the metal frame 91. Here, the plurality of dice 13 are formed from the semiconductor wafer or semiconductor chip.

Referring FIG. 9D, a metal wire 94 is bonded to connect the die 93 below. Normally the metal wire 94 is formed by the gold wire.

Next, as FIG. 9E, molding parts of the metal frame 91 are achieved to expose parts of the metal frame 91 by a chemical compound such as plastic. Here, External pressure is introduced in the step to prevent the chemical compound from coating on the lower surface of the metal frame 91 portions.

Finally, as FIG. 9F shows, a plurality of metal balls 96 is placed to connect under other parts of the metal frame 91, which is the bottom portion of the metal frame 91, so that the individual die package 98 is obtained.

In the practical, the tenth embodiment of the invention is provided for the 64M SDRAM fabrication. In addition, the die specification is designed for the 0.18 um wire width and the package size is about 9×12 mm.

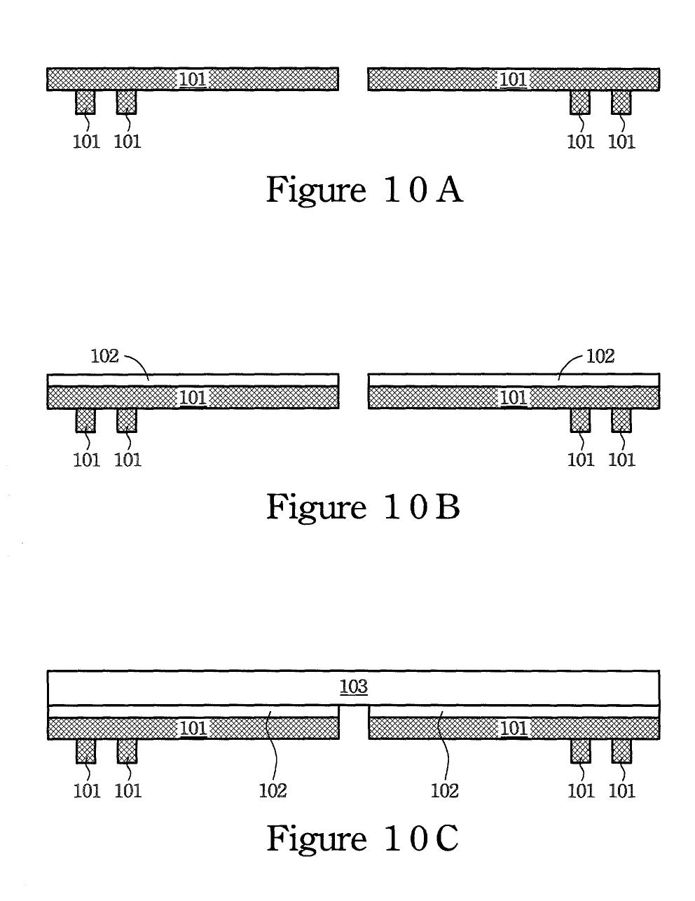

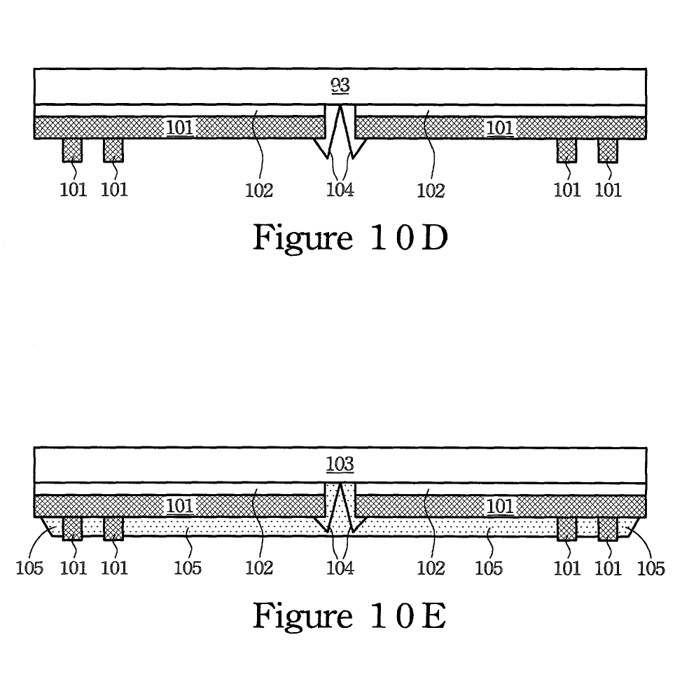

Consequentially, the tenth embodiment of the present invention is showed as FIG. 10A. A metal frame 101, such as lead frame 101 is provided and the metal frame 101 is formed as a specific pattern. Especially the specific pattern is defined by the lithography including stamping process etc.

With reference to FIG. 10B, a material 92 is laminated on the backside surface of a die 93. The material 102 is used by adhesive material as a tape.

Referring to FIG. 10C, the die 103 is located upon the metal frame 101. Here, the plurality of dice 13 are formed from the semiconductor wafer or semiconductor chip.

Referring FIG. 10D, a metal wire 104 is bonded to connect the die 103 below. Normally the metal wire 104 is formed by the gold wire.

Finally, as FIG. 10E, molding parts of the metal frame 101 are achieved to expose parts of the metal frame 101 by a chemical compound such as plastic. Here, External pressure is introduced in the step to prevent the chemical compound from coating on the lower surface of the metal frame 101 portions.

In the practical, using the lead frame and BGA, the eighth embodiment of the invention is provided for the 64M SDRAM fabrication. Especially the die specification is designed for the 0.18 um wire width and the package size is about 9×12 mm.

Therefore, according to the above statement, the advantages for the invention can be describes as the followings:

1. The high frequency requirement is easily achieved.

2. The package cost can be exactly decreased.

3. The cycle time will be shorten.

According to the above statement, in the first feature of the above embodiment, the method for packing a semiconductor wafer is described as the followings:

Firstly, a metal frame having a specific pattern is provided. Then, a material on the backside surface of a plurality of dice is laminated by using a adhesive material as a tape. The plurality of dice is located upon the metal frame. A metal wire is bonded to connect the plurality of dice below. Next, first molding the plurality of dice and parts of the metal frame to expose parts of the metal frame is achieved by a chemical compound to seal the plurality of dice. Then, the second individual molding the plurality of dice is carried out by the chemical compound. Next, a plurality of metal balls is placed to connect under other parts of the metal frame as an individual die package. Finally, the individual die package is punched to pack the semiconductor die.

Also, in the second feature of the above embodiment, the method for packing a semiconductor wafer is described as the followings:

Firstly, a metal frame having a specific pattern is provided. Then, a material on the backside surface of a plurality of dice is laminated by using an adhesive material as a tape. The plurality of dice is located upon the metal frame. A metal wire is bonded to connect the plurality of dice below. Next, first molding the plurality of dice and parts of the metal frame to expose parts of the metal frame is achieved by a chemical compound to seal the plurality of dice. Then, the second conformal molding the plurality of dice is carried out by the chemical compound. Next, a plurality of metal balls is placed to connect under other parts of the metal frame as an individual die package. Finally, the individual die package is singulated to pack the semiconductor die.

Although specific embodiments have been illustrated and described, it will be obvious to those skilled in the art that various modifications may be made without departing from what is intended to be limited solely by the appended claims.

What is claimed is:

1. A method for packing a semiconductor die, comprising:
providing a metal frame having a specific pattern;
laminating a material on the backside surface of a plurality of dice by using an adhesive material as a tape;
locating the plurality of dice upon the metal frame;
bonding a metal wire to connect the plurality of dice below;
first molding the plurality of dice and parts of the metal frame to expose parts of the metal frame by a chemical compound;
second individual molding the plurality of dice by the chemical compound;
placing a plurality of metal balls to connect under other parts of the metal frame as an individual die package; and
punching the individual die package as a finished die package to pack the semiconductor die.

2. The method according to claim 1, wherein said specific pattern is defined by lithography process.

3. The method according to claim 1, wherein said metal frame is lead frame.

4. The method according to claim 1, wherein said die is formed from semiconductor wafer.

5. The method according to claim 1, wherein said die comprises semiconductor chip.

6. The method according to claim 1, wherein said chemical compound comprises plastic.

7. A method for packing a semiconductor die, comprising:
providing a metal frame having a specific pattern;
laminating a material on the backside surface of a plurality of dice by using an adhesive material as a tape;
locating the plurality of dice upon the metal frame;
bonding a metal wire to connect the plurality of dice below;
first molding the plurality of dice and parts of the metal frame to expose another parts of the metal frame by a chemical compound;
second conformal molding the plurality of dice by the chemical compound;
placing a plurality of metal balls to connect under other parts of the metal frame as a conformal die package; and
singulating the conformal die package as a finished die package to pack the semiconductor die.

8. The method according to claim 7, wherein said specific pattern is defined by lithography process.

9. The method according to claim 7, wherein said metal frame is lead frame.

10. The method according to claim 7, wherein said die is formed from semiconductor wafer.

11. The method according to claim 7, wherein said die comprises semiconductor chip.

12. The method according to claim 7, wherein said chemical compound comprises plastic.

13. A method for packing a semiconductor die, comprising:
providing a metal frame having a specific pattern;
laminating a material on the backside surface of a plurality of dice by using an adhesive material as a tape;
locating the plurality of dice upon the metal frame;
bonding a metal wire to connect the plurality of dice below;
first molding the plurality of dice and parts of the metal frame to expose parts of the metal frame by a chemical compound;
second individual molding the plurality of dice by the chemical compound as an individual die package; and
punching the individual die package as a finished die package to pack the semiconductor die.

14. The method according to claim 13, wherein said specific pattern is defined by lithography process.

15. The method according to claim 13, wherein said metal frame is lead frame.

16. The method according to claim 13, wherein said die is formed from semiconductor wafer.

17. The method according to claim 13, wherein said die comprises semiconductor chip.

18. The method according to claim 13, wherein said chemical compound comprises plastic.

19. A method for packing a semiconductor die, comprising:
providing a metal frame having a specific pattern;
laminating a material on the backside surface of a plurality of dice by using an adhesive material as a tape;
locating the plurality of dice upon the metal frame;
bonding a metal wire to connect the plurality of dice below;
first molding the plurality of dice and parts of the metal frame to expose another parts of the metal frame by a chemical compound;
second conformal molding the plurality of dice by the chemical compound as an conformal die package; and
singulating the conformal die package as a finished die package to pack the semiconductor die.

20. The method according to claim 19, wherein said specific pattern is defined by lithography process.

21. The method according to claim 19, wherein said metal frame is lead frame.

22. The method according to claim 19, wherein said die is formed from semiconductor wafer.

23. The method according to claim 19, wherein said die comprises semiconductor chip.

24. The method according to claim 19, wherein said chemical compound comprises plastic.

25. A method for packing a semiconductor die, comprising:
providing a metal frame having a specific pattern;
laminating a material on the backside surface of a plurality of dice by using an adhesive material as a tape;
locating the plurality of dice upon the metal frame;
bonding a metal wire to connect the plurality of dice below;
first molding the plurality of dice and parts of the metal frame to expose parts of the metal frame by a chemical compound;
second individual molding the plurality of dice by the chemical compound;
placing a plurality of metal balls to connect under other parts of the metal frame as an individual die package; and
punching the individual die package as a finished die package to pack the semiconductor die.

26. The method according to claim 25, wherein said specific pattern is defined by lithography process.

27. The method according to claim 25, wherein said metal frame is lead frame.

28. The method according to claim 25, wherein said die is formed from semiconductor wafer.

29. The method according to claim 25, wherein said die comprises semiconductor chip.

30. The method according to claim 25, wherein said chemical compound comprises plastic.

31. A method for packing a semiconductor die, comprising:
providing a metal frame having a specific pattern;
laminating a material on the backside surface of a plurality of dice by using an adhesive material as a tape;
locating the plurality of dice upon the metal frame;
bonding a metal wire to connect the plurality of dice below;
first molding around a first side of the plurality of dice as a first housing and parts of the metal frame to expose another parts of the metal frame by a chemical compound, wherein a top surface of the plurality of dies is exposed;
second conformal molding around a second side of the first housing as an conformal die package by the chemical compound, wherein the top surface of the plurality of dice is exposed; and
singulating the conformal die package as a finished die package to pack the semiconductor die.

32. The method according to claim 31, wherein said specific pattern is defined by lithography process.

33. The method according to claim 31, wherein said metal frame is lead frame.

34. The method according to claim 31, wherein said die is formed from semiconductor wafer.

35. The method according to claim 31, wherein said die comprises semiconductor chip.

36. The method according to claim 31, wherein said chemical compound comprises plastic.

37. A method for packing a semiconductor die, comprising:
providing a metal frame having a specific pattern;
laminating a material on the backside surface of a plurality of dice by using an adhesive material as a tape;
locating the plurality of dice upon the metal frame;
bonding a metal wire to connect the plurality of dice below;
first molding around a first side of the plurality of dice as a first housing and parts of the metal frame to expose another parts of the metal frame by a chemical compound, wherein a top surface of the plurality of dice is exposed;
second individual molding around a second side of the first housing as an individual die package by the chemical compound, wherein the top surface of the plurality of dice is exposed;
placing a plurality of metal balls to connect under other parts of the metal frame as an individual die package; and
punching the individual die package as a finished die package to pack the semiconductor die.

38. The method according to claim 37, wherein said specific pattern is defined by lithography process.

39. The method according to claim 37, wherein said metal frame is lead frame.

40. The method according to claim 37, wherein said die is formed from semiconductor wafer.

41. The method according to claim 37, wherein said die comprises semiconductor chip.

42. The method according to claim 37, wherein said chemical compound comprises plastic.

43. A method for packing a semiconductor die, comprising:
providing a metal frame having a specific pattern;
laminating a material on the backside surface of a plurality of dice by using an adhesive material as a tape;
locating the plurality of dice upon the metal frame;
bonding a metal wire to connect the plurality of dice below;
first molding around a first side of the plurality of dice as a first housing and parts of the metal frame to expose another parts of the metal frame by a chemical compound, wherein a top surface of the plurality of dice is exposed;
second conformal molding around a second side of the first housing as an conformal die package by the chemical compound, wherein the top surface of the plurality of dice is exposed; and
singulating the conformal die package as a finished die package to pack the semiconductor die.

44. The method according to claim 43, wherein said specific pattern is defined by lithography process.

45. The method according to claim 43, wherein said metal frame is lead frame.

46. The method according to claim 43, wherein said die is formed from semiconductor wafer.

47. The method according to claim 43, wherein said die comprises semiconductor chip.

48. The method according to claim 43, wherein said chemical compound comprises plastic.

49. A method for packing a semiconductor die, comprising:
providing a metal frame having a specific pattern;
laminating a material on the backside surface of a plurality of dice by using an adhesive material as a tape;
locating the plurality of dice upon the metal frame;
bonding a metal wire to connect the plurality of dice below;
molding parts of the metal frame to expose parts of the metal frame by a chemical compound to seal the plurality of dice;
placing a plurality of metal balls to connect under other parts of the metal frame as an individual die package; and
punching the individual die package as a finished die package to pack the semiconductor die.

50. The method according to claim 49, wherein said specific pattern is defined by lithography process.

51. The method according to claim 49, wherein said metal frame is lead frame.

52. The method according to claim 49, wherein said die is formed from semiconductor wafer.

53. The method according to claim 49, wherein said die comprises semiconductor chip.

54. The method according to claim 49, wherein said chemical compound comprises plastic.

55. A method for packing a semiconductor die, comprising:
providing a metal frame having a specific pattern;
laminating a material on the backside surface of a plurality of dice by using an adhesive material as a tape;
locating the plurality of dice upon the metal frame;
bonding a metal wire to connect the plurality of dice below;
molding parts of the metal frame to expose parts of the metal frame by a chemical compound to seal the plurality of dice;
placing a plurality of metal balls to connect under other parts of the metal frame as an individual die package; and
punching the individual die package as a finished die package to pack the semiconductor die.

56. The method according to claim 55, wherein said specific pattern is defined by lithography process.

57. The method according to claim 55, wherein said metal frame is lead frame.

58. The method according to claim 55, wherein said die is formed from semiconductor wafer.

59. The method according to claim 55, wherein said die comprises semiconductor chip.

60. The method according to claim 55, wherein said chemical compound comprises plastic.
